(19) United States
(12) Patent Application Publication
(10) Pub. No.: US 2009/0051369 A1
(43) Pub. Date: Feb. 26, 2009

(54) SYSTEM AND METHOD FOR MEASURING ADHESION FORCES IN MEMS DEVICES

(75) Inventors: Lior Kogut, Haifa (IL); Ming-Hau Tung, San Francisco, CA (US); Sauri Gudlavalleti, San Jose, CA (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM Incorporated, San Diego, CA (US)

(21) Appl. No.: 11/842,914

(22) Filed: Aug. 21, 2007

(51) Int. Cl. G01R 27/26; G01J 3/46; G02B 5/08; G06F 19/00; G01N 27/00

(52) U.S. Cl. 324/658; 324/71.1; 356/402; 359/839; 702/35

(57) ABSTRACT

A MEMS test device comprises a flexible beam spaced apart from an optical stack. The MEMS test device includes a reflective layer and a partially reflective layer, such that a change in the position of the MEMS test device can be observed without the use of an external interferometer. The flexible beam may be cantilevered or fixed at each end. The flexible beam may include a shoe suspended from the side of the beam facing the optical stack, to provide a fixed contact area. An array of MEMS test devices may be used to determine compliance, or to calculate adhesion forces.

### BACKGROUND OF THE INVENTION

1. Field of the Invention

The present invention relates to microelectromechanical systems (MEMS).

2. Description of the Related Art

MEMS include micro mechanical elements, actuators, and electronics. Micromechanical elements may be created using deposition, etching, and/or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY OF THE INVENTION

In one aspect, an array of MEMS devices includes an optical stack located over a substrate, the optical stack including an electrode layer and a partially reflective layer, an array of flexible beams spaced apart from the optical stack by an air gap, and reflective surfaces positioned on the side of the beams facing the optical stack, where the stiffness of the beams varies so that actuation of particular beams is indicative of the stiffness of the beams.

In one aspect, an array of MEMS devices includes an optical stack located over a substrate, the optical stack including an electrode layer and a partially reflective layer, an array of flexible beams spaced apart from the optical stack by an air gap, and contact portions positioned on the side of the flexible beams facing the array, where the contact portions include a reflective surface, and where the size of the contact portions vary so that sustained adhesion between the contact portions and the optical stack is indicative of adhesion forces within the MEMS device.

In one aspect, an array of MEMS devices includes an optical stack located over a substrate, the optical stack including apartially reflective layer, an array of flexible beams spaced apart from the optical stack by an air gap, where application of a voltage across the beams and the optical stack is inhibited, and reflective surfaces positioned on the side of the beams facing the optical stack, where sustained adhesion of particular beams to the optical stack is indicative of non-electrostatic adhesion forces within the MEMS device.

In one aspect, a method of fabricating an array of test devices includes forming an optical stack over a substrate, the optical stack including an electrode layer and a partially reflective layer, forming a plurality of beams spaced apart from the substrate by an air gap, where the beams include a reflective portion facing the substrate, and where the stiffness of the beams varies across the array.

In one aspect, a method of fabricating an array of test devices includes forming an optical stack over a substrate, the optical stack including an electrode layer and a partially reflective layer, forming a plurality of beams, where each of the plurality of beams includes a reflective shoe member spaced apart from the optical stack via an air gap, and where the size of the reflective shoe members varies in the array.

In one aspect, a method of fabricating an array of test devices includes forming an optical stack over a substrate, the optical stack including a partially reflective layer, and forming a plurality of beams spaced apart from the substrate by an air gap, where the beams are not electrostatically actuatable towards the optical stack, and where the beams include a reflective surface facing the optical stack.

In one aspect, a method of testing an array of MEMS devices includes providing an array of beams spaced apart from an optical stack by an air gap, where the beams include a reflective layer on their lower surface and have a stiffness that varies across the array, and where the optical stack includes a partially reflective layer and a lower electrode, determining a predicted actuation voltage for each of the array of beams, applying a first voltage between the array of beams and the lower electrode, determining, without the aid of an external interferometer, which of the array of beams have been actuated through the air gap towards the electrode due to application of the first voltage, and comparing the first voltage with the predicted actuation voltages for each of the beams.

In one aspect, a method of testing an array of MEMS devices includes providing an array of beams having a reflective layer on their lower surface, where the beams are spaced apart from a partially reflective layer and a first electrode by an air gap, where the stiffness of the beams varies across a length of the array, applying a first voltage between the array of beams and the first electrode sufficient to cause each of the plurality of beams to actuate through the air gap and come into contact with an underlying layer, releasing the first voltage, determining, without the aid of an external interferometer, which of the array of beams remain unreleased, and determining the adhesion energy holding the unreleased beams in place.

In one aspect, a method of testing an array of MEMS devices includes providing an array of beams having a reflective contact area on their lower surface, where the beams are spaced apart from a partially reflective layer and a first electrode by an air gap, where the size of the contact area varies across a length of the array, applying a first voltage between the array of beams and the first electrode sufficient to cause each of the plurality of beams to actuate through the air gap and come into contact with an underlying layer, releasing the first voltage, determining, without the aid of an external interferometer, which of the array of beams remain unreleased, and determining the adhesion energy holding the unreleased beams in place.

In one aspect, method of testing an array of MEMS devices includes providing an array of beams spaced apart from a lower electrode by an air gap, where the beams include a conductive portion and have a stiffness that varies across the array, determining a predicted actuation energy for each of the array of beams, applying a first voltage between the array of beams and the lower electrode, determining, based on the electrical characteristics of the MEMS devices, which of the array of beams have been actuated through the air gap towards the electrode due to application of the first voltage, and comparing the first voltage with the predicted actuation voltages for each of the beams.

In one aspect, a method of testing an array of MEMS devices includes providing an array of beams spaced apart from a partially reflective layer and a first electrode by an air gap, where the stiffness of the beams varies across a length of the array, applying a first voltage between the array of beams and the first electrode sufficient to cause each of the plurality of beams to actuate through the air gap and come into contact with an underlying layer, releasing the first voltage, determining, based on the electrical characteristics of the MEMS devices, which of the array of beams remain unreleased, and determining the adhesion energy holding the unreleased beams in place.

In one aspect, a method of testing an array of MEMS devices, including providing an array of beams having a contact area on their lower surface, where the beams are spaced apart from a first electrode by an air gap, and where the size of the contact area varies across a length of the array, applying a first voltage between the array of beams and the first electrode sufficient to cause each of the plurality of beams to actuate through the air gap and come into contact with an underlying layer, releasing the first voltage, determining, based on the electrical characteristics of the MEMS devices, which of the array of beams remain unreleased, and determining the adhesion energy holding the unreleased beams in place.

In one aspect, an array of MEMS devices includes means for reflecting incident light, means for partially reflecting incident light, means for supporting the reflecting means, and means for actuating the reflecting means towards the partially reflecting means, where the actuation of particular reflecting means is indicative of the stiffness of the supporting means.

In one aspect, an array of MEMS devices includes means for reflecting incident light, means for partially reflecting incident light, means for actuating the reflecting means towards the partially reflecting means, and means for restoring the reflecting means to positions away from the partially reflecting means, where the restoration of particular reflecting means is indicative of adhesion forces within the MEMS device.

In one aspect, an array of MEMS devices includes means for reflecting incident light, means for partially reflecting incident light, means for inhibiting the application of a voltage between the reflecting means and the partially reflecting means, and means for restoring the reflecting means to positions away from the partially reflecting means, where the restoration of particular reflecting means is indicative of non-electrostatic adhesion forces within the MEMS device.

In one aspect, a computer readable medium includes instructions for testing an array of MEMS devices, the instructions including, instructions for applying a voltage across an array of test structures, where the test structures include integrated interferometric modulators, and instructions for determining which of the test structures have actuated.

In another aspect, a computer readable medium includes instructions for testing an array of MEMS devices, the instructions including instructions for applying a time-varying voltage across an array of test structures for a predetermined time period, where the test structures include integrated interferometric modulators, and instructions for determining which of the test structures have returned to an unactuated state.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIG. 5A illustrates one exemplary frame of display data in the 3×3 interferometric modulator display of FIG. 2.

FIG. 5B illustrates one exemplary timing diagram for row and column signals that may be used to write the frame of FIG. 5A.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8 is a cross sectional view of an embodiment of a test device.

FIG. 9 is a bottom view of an array of test devices having beams of varying length.

FIG. 10 is a flow chart illustrating a process for testing an array of test structures to determine compliance.

FIG. 11 is a flow chart illustrating another process for testing an array or test structures to determine adhesion forces.

FIGS. 12A-12C are cross sectional views illustrating various steps in a process for fabricating a test structure having a shoe supported by a beam fixed at both ends.

FIG. 13 is a cross sectional view of a step in a process for fabricating a test structure having a shoe supported by a cantilevered beam.

FIGS. 14A-14B are cross sectional views illustrating various steps in a process for fabricating a test structure having a shoe supported by a beam having rigid support posts at both ends.

FIG. 15 is a cross sectional view of a step in a process for fabricating a test structure having a shot supported by a cantilevered beam having a rigid support post at one end.

FIG. 16 is a cross sectional view of a passive test structure having a shoe supported by a beam fixed at each end.

FIG. 17 is a cross sectional view of a test structure.

### DETAILED DESCRIPTION OF THE PREFERRED EMBODIMENT

The following detailed description is directed to certain specific embodiments of the invention. However, the invention can be embodied in a multitude of different ways. In this description, reference is made to the drawings wherein like parts are designated with like numerals throughout. As will be apparent from the following description, the embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

Adhesion forces play a critical role in the sustained operability of MEMS devices, often causing the eventual failure of a MEMS device due to permanent adhesion of moving components of a MEMS device. Knowledge of adhesion forces is critical to the design of a MEMS device which provides sufficient restoring force to counteract the adhesion forces. MEMS devices are described herein which can be used to measure adhesion forces in a straightforward manner, without the need for an external interferometer to determine the state of the MEMS test devices. These test devices can also be used to measure compliance, and to identify inconsistencies in the fabrication process, both at different locations on the same wafer and across different wafers and/or lots.

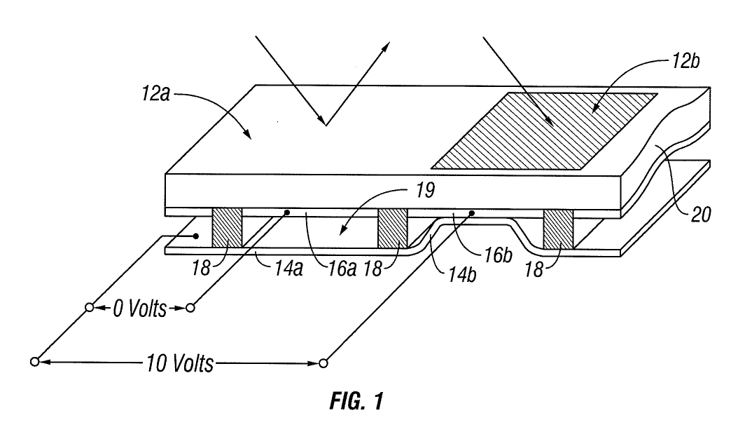

One interferometric modulator display embodiment comprising an interferometric MEMS display element is illustrated in FIG. 1. In these devices, the pixels are in either a bright or dark state. In the bright (“on” or “open”) state, the display element reflects a large portion of incident visible light to a user. When in the dark (“off” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical gap with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise several fused layers, which can include an electrode layer, such as indium tin oxide (ITO), a partially reflective layer, such as chromium, and a transparent dielectric. The optical stack 16 is thus electrically conductive, partially transparent, and partially reflective, and may be fabricated, for example, by depositing one or more of the above layers onto a transparent substrate 20. The partially reflective layer can be formed from a variety of materials that are partially reflective such as various metals, semiconductors, and dielectrics. The partially reflective layer can be formed of one or more layers of materials, and each of the layers can be formed of a single material or a combination of materials.

In some embodiments, the layers of the optical stack 16 are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device.

With no applied voltage, the gap 19 remains between the movable reflective layer 14a and optical stack 16a, with the movable reflective layer 14a in a mechanically relaxed state, as illustrated by the pixel 12a in FIG. 1. However, when a potential difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by pixel 12b on the right in FIG. 1. The behavior is the same regardless of the polarity of the applied potential difference. In this way, row/column actuation that can control the reflective vs. non-reflective pixel states is analogous in many ways to that used in conventional LCD and other display technologies.

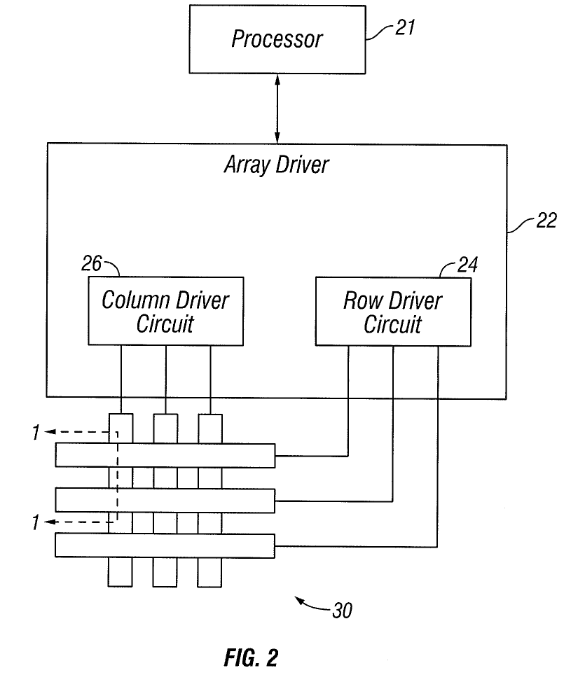

FIGS. 2 through 5B illustrate one exemplary process and system for using an array of interferometric modulators in a display application.

FIG. 2 is a system block diagram illustrating one embodiment of an electronic device that may incorporate aspects of the invention. In the exemplary embodiment, the electronic device includes a processor 21 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

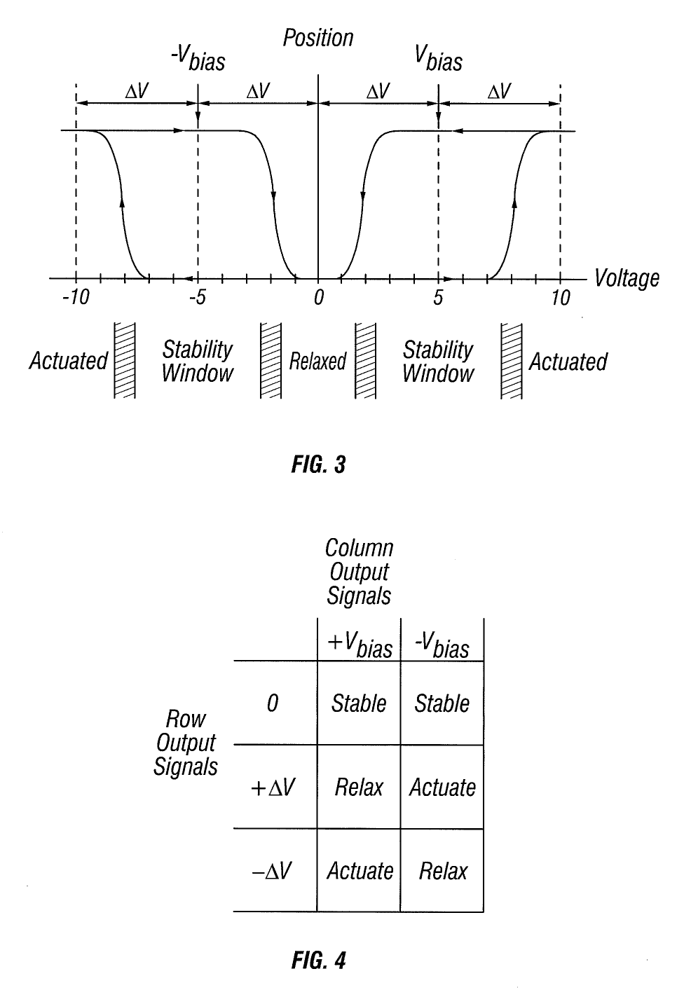

In one embodiment, the processor 21 is also configured to communicate with an array driver 22. In one embodiment, the array driver 22 includes a row driver circuit 24 and a column driver circuit 26 that provide signals to a display array or panel 30. The cross section of the array illustrated in FIG. 1 is shown by the lines 1-1 in FIG. 2. For MEMS interferometric modulators, the row/column actuation protocol may take advantage of a hysteresis property of these devices illustrated in FIG. 3. It may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. Thus, there exists a window of applied voltage, about 3 to 7 V in the example illustrated in FIG. 3, within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, actuating the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of protocols for driving row and column electrodes of pixel arrays to produce display frames are also well known and may be used in conjunction with the present invention.

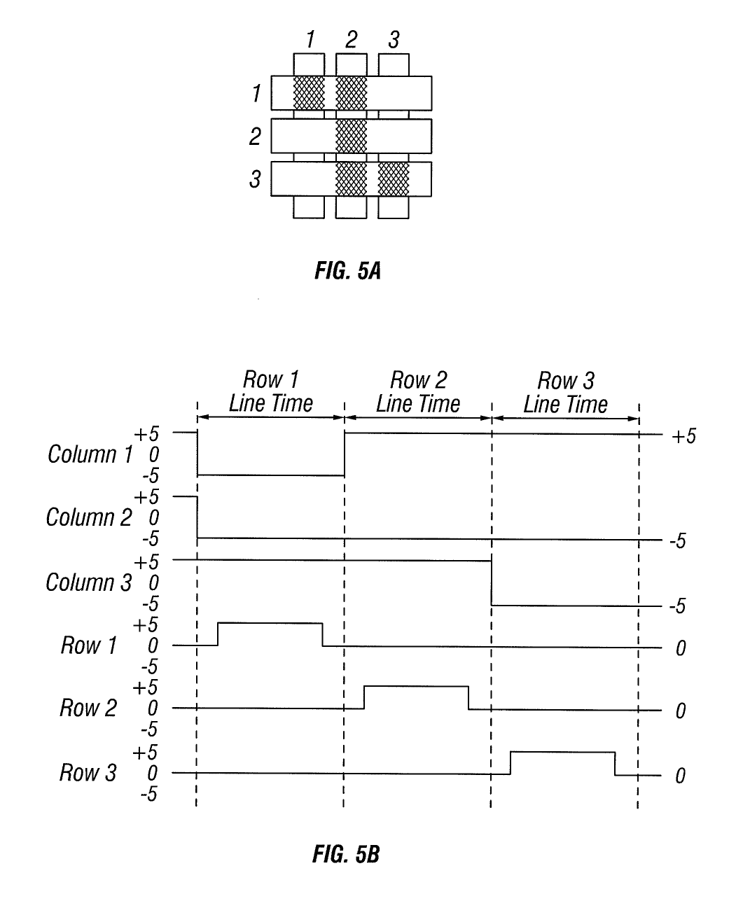

FIGS. 4, 5A, and 5B illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts, respectively. Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, it will be appreciated that voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the systems and methods described herein.

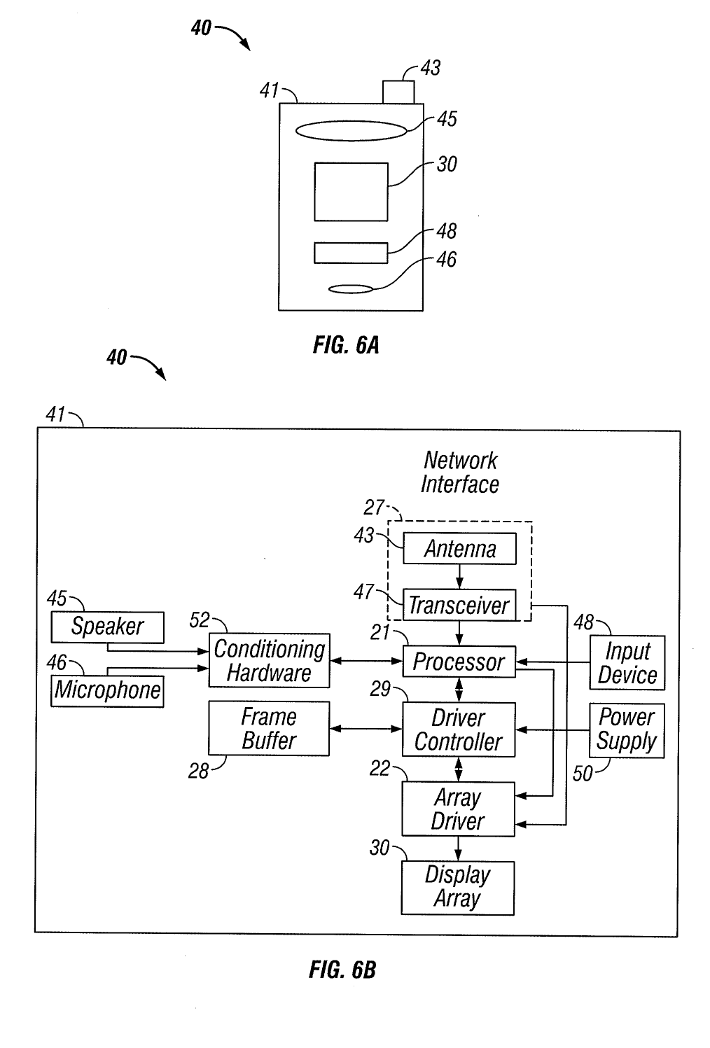

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes as are well known to those of skill in the art, including injection molding and vacuum forming. In addition, the housing 41 may be made from any of a variety of materials, including, but not limited to, plastic, metal, glass, rubber, and ceramic, or a combination thereof. In one embodiment, the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device, as is well known to those of skill in the art. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43, which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28 and to an array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one or more devices over a network. In one embodiment, the network interface 27 may also have some processing capabilities to relieve requirements of the processor 21. The antenna 43 is any antenna known to those of skill in the art for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS, or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, or a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell including a plastic solar cell, and solar-cell paint. In another embodiment, power supply 50 is configured to receive power from a wall outlet.

In some embodiments, control programmability resides, as described above, in a driver controller which can be located in several places in the electronic display system. In some embodiments, control programmability resides in the array driver 22. Those of skill in the art will recognize that the above-described optimizations may be implemented in any number of hardware and/or software components and in various configurations.

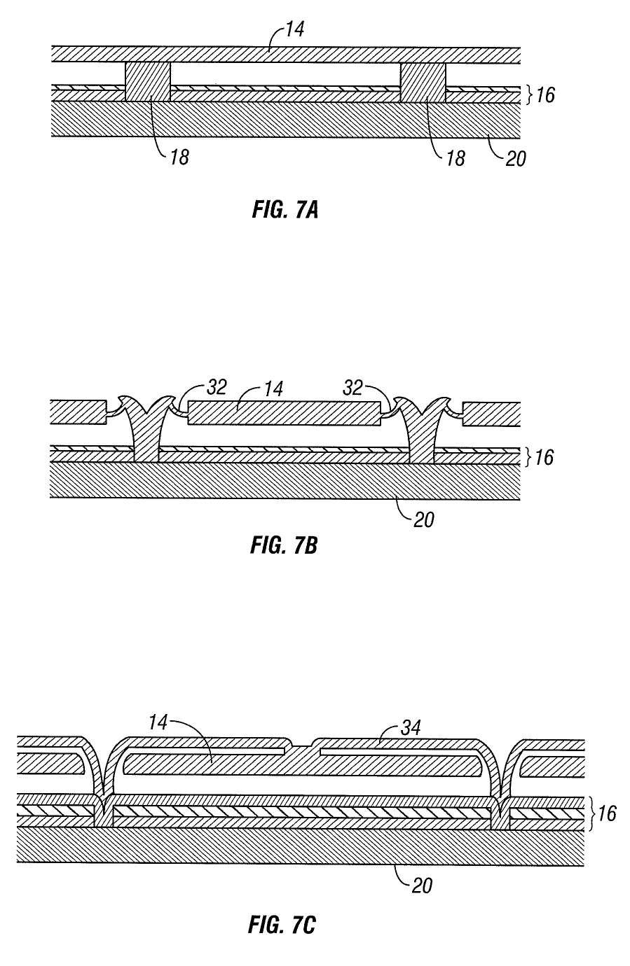

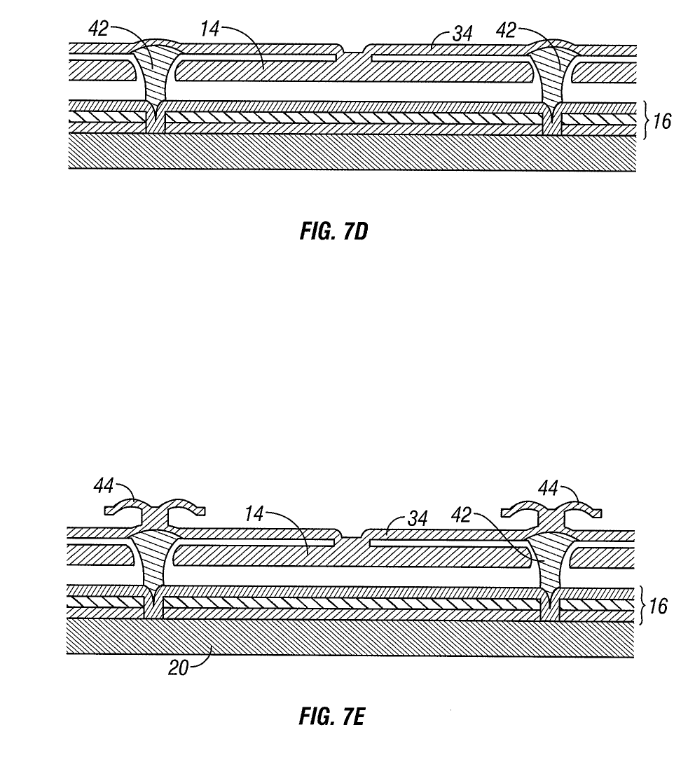

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 is attached to supports at the corners only, on tethers 32. In FIG. 7C, the moveable reflective layer 14 is suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the gap, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C, as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the modulator is arranged. In these embodiments, the reflective layer 14 optically shields the portions of the interferometric modulator on the side of the reflective layer opposite the substrate 20, including the deformable layer 34. This allows the shielded areas to be configured and operated upon without negatively affecting the image quality. Such shielding allows the bus structure 44 in FIG. 7E, which provides the ability to separate the optical properties of the modulator from the electromechanical properties of the modulator, such as addressing and the movements that result from that addressing. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

Adhesion forces play a critical role in the operation and reliability of devices on a MEMS scale. Certain MEMS devices, such as interferometric modulators of the type discussed above, are particularly susceptible to eventual failure due to permanent adhesion, otherwise known as stiction. Among the factors contributing to this susceptibility are the large surface area to volume ratio, the relatively smooth surfaces, small interfacial gaps, charge trapped within the MEMS device, and the small restoring forces to counteract the adhesion forces. The causes of permanent adhesion during MEMS operation are not well understood, limiting to some extent the efficiency and reliability of these devices. However, determination of adhesion energy will facilitate the design of test structures wherein the restoring forces are greater than the adhesion forces.

By providing test structures, also known as process control monitors (PCMs), restoration and adhesion forces can be determined. These test structures can also be used to compare different panels of MEMS devices, in order to provide an indication of the quality of the panel, or to provide insight into the effects of the manufacturing process.

Embodiments of the test devices described herein include a movable member suspended over a surface. The movable member may be suspended over the surface via a distinct support member, or the movable member may be itself fixed to the surface at least one end. In certain embodiments, the support member may be cantilevered, and fixed to the surface at only one end. In other embodiments, the support member may be fixed at both ends. An array of such test devices may be provided, where certain properties of the test devices vary in the array. In certain embodiments, the stiffness of the support member varies. In other embodiments, the size of the contact area on the movable member which comes into contact with the surface varies. In certain embodiments, the test structures are active devices in which the movable member can be driven towards the surface via electrostatic forces. In other embodiments, the test structures may be a passive device in which capillary forces attract the movable member to the surface.

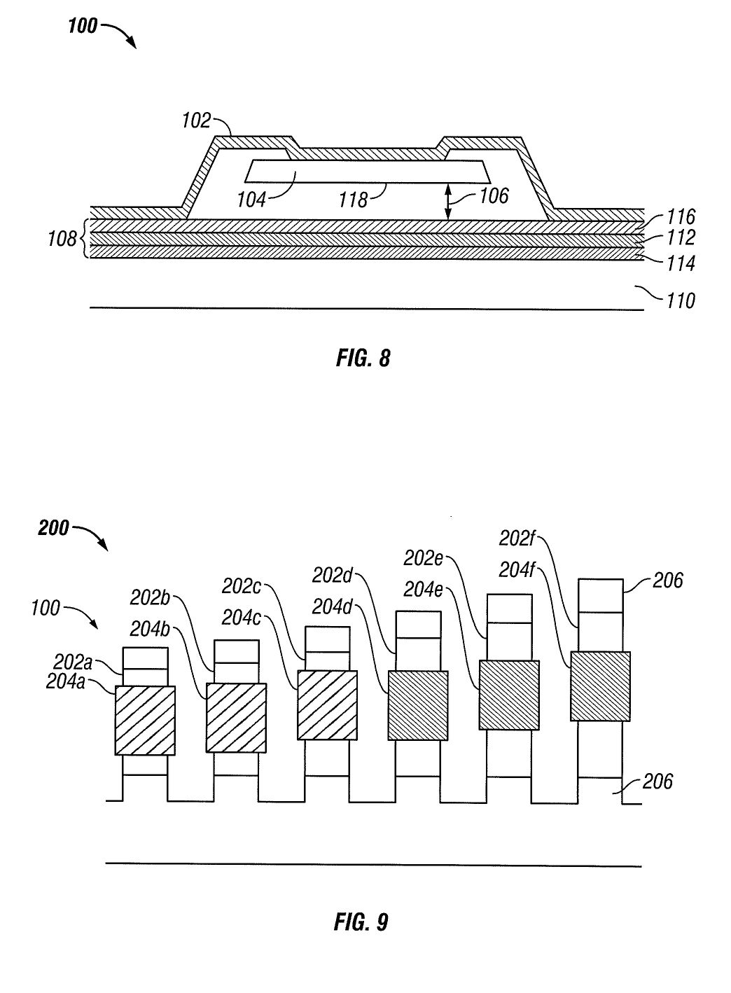

FIG. 8 illustrates an embodiment of a fixed-fixed test structure 100 having a distinct support structure. The test structure 100 comprises a beam 102, fixed at each end, from which a movable contact member, referred to herein as a shoe 104, is suspended. The shoe 104 is spaced apart from the underlying layer via an air gap 106. Advantageously, the test device comprises an optical stack 108 formed on a transmissive substrate 110, where the optical stack includes a partially reflective layer 112. In embodiments in which the shoe 104 comprises a reflective layer, the air gap 106 thus functions as an interferometric cavity. An observer viewing the test structure 100 through the transmissive substrate 110 will thus be able to easily observe a change in the position of the shoe 104 relative to the optical stack 108 as the light reflected by the interferometric test structure 100 is dependent on the height of the interferometric gap 106.

In order to actuate the movable shoe 104 towards the optical stack 108, the optical stack 108 comprises an electrode 114. In embodiments in which the beam 102 is conductive, the optical stack may further comprise a dielectric layer 116 to electrically isolate the beam 102 from the electrode 114. By applying a voltage across the shoe 104 and the electrode 114 (such as via a conductive beam 102, the shoe 104 may be electrostatically actuated towards the optical stack 108, eventually bringing the shoe 104 into contact with the optical stack.

In certain embodiments, the beam 102 comprises a conductive material, such as nickel. Similarly, the shoe 104 advantageously comprises a conductive and reflective material, such as aluminum. In certain embodiments, the dielectric layer 116 comprises a dielectric material such as SiO2, the partially reflective layer 112 comprises a partially reflective thickness of a material such as chromium, and the electrode layer 114 comprises a material such as indium tin oxide (ITO). It will be understood, however, that a variety of materials may be suitable for use in each of the components of the test device 100.

As noted above, in an array of such test devices 100, either the stiffness of the beams 102 or the size of the contact area 118 on the underside of the shoe 104 may be varied. It will be understood that by varying the stiffness of the beams 102, the restoring force of the test structure 100 will be varied. The stiffness of the beam 102 may be varied, e.g., by altering the thickness of the beam, the width of the beam, the beam material, or the stress of the beam. As it is easiest to vary the length or width of the beam, this method for varying the stiffness will be discussed below, but it will be understood that other methods are contemplated and within the scope of the invention. Similarly, the adhesion forces between the shoe 104 and the surface of the optical stack 108 may be increased, e.g., by increasing the size or shape of contact area 118.

Stiction will occur when the restoring force is less than the adhesion force. The restoring force of a MEMS device can be readily calculated based on the structure of the MEMS device and the height of the air gap. By varying either the restoring force or the adhesion force over the array, the critical point at which the restoring force is either just below the adhesion force or just above the adhesion force can be identified, and by using the known parameters of the MEMS device at the critical point, the adhesion force can then be determined. Thus, an array of test devices such as test device 100 having a parameter which varies across the test devices in the array can be used to visually identify the MEMS device at the critical parameter. In particular, in an embodiment such as that described with respect to test device 100, in which the test device comprises an interferometric cavity, the visual identification can advantageously be done without the need for an external interferometer.

In addition to visual determination of the state of the test structure, the state of the test structure may be determined in other ways, such through testing or monitoring of the electrical characteristics of the test structure. For example, in embodiments in which the test structure comprises two conductive surfaces substantially parallel to one another, those conductive surfaces will act as a capacitor. By determining or monitoring the capacitance of the test structure, the position or state of the test structure may be determined, and any changes in the position or state can be readily identified. It will be understood that when using such a method, the reflectivity of various layers within the test structure may be unimportant, as the determination of the state of the test structure is made based on the electrical characteristics of the test structure. Thus, such a test structure need not include reflective or partially reflective layers.

Embodiments of such a test device may differ from interferometric modulator-based displays, although in certain embodiments the test devices may be provided alongside interferometric modulator based displays, and the fabrication of the test devices may include some of all of the steps utilized to fabricate the displays. In contrast to displays, where it is desirable to have a large percentage of the display functioning as active area, the active area of the test devices need not be as large as possible relative to the test device. Furthermore, in order to provide a more accurate determination of various factors, a large amount of test structures with differing parameters may be provided. For example, embodiments of test arrays may comprise at least 4 structures having differing parameters. Other embodiments may have 5, 6, 7, 8, 9, 10 or more structures having differing parameters.

FIG. 9 depicts a view from below such an array 200 of test devices 100 in which the length of the beams 202a-202f varies across the array, thereby varying the stiffness of the beams, which increases as the length of the beams decreases. The array 200 is advantageously arranged in order of stiffness, although other arrangements are possible. The beams 202a-202f are fixed at each end at sections 206 and spaced apart from the underlying layers (e.g., optical stack 108) in the middle of the beams. Suspended from the beams 202a-202f are shoes 204a-204f, which have a substantially square contact area on the underside of the beam, with each shoe being the same size. In the illustrated embodiment, the dimensions of the films in the optical stack 108 are chosen such that the test devices reflect some color while in an unactuated state, and reflect substantially no light when in an actuate state. Thus, it can be seen in FIG. 9 that the shoes 204a-204c are in an unactuated position, in which some color of light is reflected, and that shoes 204d-204f are in an actuated state, in which the test devices appear black. Thus, it can be seen that the restoring force is equal to the adhesion force at some stiffness between that of beam 202c and beam 202d, which may be referred to as the critical devices. The array 200 thus provides six test structures 100 having differing parameters (in this case the length, and thus the stiffness, of the beam). Testing methods using an array 200 or similar arrays are described in greater detail below.

It will also be understood that in addition to determining whether the device is in an actuated or an unactuated state, the height of the air gap of unactuated test structures, such as those comprising shoes 204a-204c, can be readily determined based on the wavelength of the light reflected by these unactuated test structures. Because the wavelength of the reflected light is a function of the height of the interferometric cavity, the wavelength of light reflected by these structures can either be measured to calculate the air gap, or compared with adjacent unactuated test structures to determine whether the air gaps are consistent across the array. It will be understood that the light reflected by these test structures may include both wavelengths in the visible spectrum and wavelengths in the non-visible spectrum. In embodiments discussed in greater detail below, the height of the air gaps in various test structures may vary in such an array, and the reflected colors can be measured to determine the various heights.

Similarly, the electrical properties of the test structure can be used to determine the state of the device. In certain embodiments, determinations based on both reflected wavelengths of light and electrical characteristics of the test devices may be used. For example, in one embodiment, analysis of the reflected wavelength may be used to make an determination of the gap size at particular stages in the testing process, and the capacitance of the test devices may be monitored to determine the state of the test structure.

A value for adhesion energy can be obtained, for example, by setting the elastic energy of a deformed member equal to the adhesion energy with the work done by adhesion, assumed to be the surface area multiplied by the attached portion of the member. Adhesion energy for a variety of structures can be then estimated through the use of the peel number, by calculating the formula for the peel number and setting the peel number equal to 1. The adhesion energy γₛ of various test devices can then be calculated. Exemplary peel number formulas for various test structures are listed below:

| Test Structure | Approximate Peel Numbers |
|---|---|
| cantilever beam | $\frac{3}{8} \frac{{Et}^{3} {h}^{2}}{{γ}_{s} {l}^{4}}$ |
| fixed-fixed beam | $( \frac{128 {Eh}^{2} {t}^{3}}{5 {γ}_{s} {l}^{4}} ) ( 1 + \frac{4 {σ}_{R} {l}^{2}}{21 {Et}^{2}} + \frac{256}{2205} {( \frac{h}{t} )}^{2} )$ |
| circular plate | $\frac{40}{3} \frac{{Eh}^{2} {t}^{3}}{( 1 - {v}^{2} ) {γ}_{s} {r}_{o}^{4}} ( 1 + \frac{51 ( 1 - {v}^{2} )}{160} \frac{{σ}_{R} {r}_{o}^{2}}{{Et}^{2}} + \frac{61}{200} {( \frac{h}{t} )}^{2} )$ |
| square plate | $\frac{186 {Eh}^{2} {t}^{3}}{( 1 - {v}^{2} ) {γ}_{s} {w}^{4}} ( 1 + \frac{27 ( 1 - {v}^{2} )}{310} \frac{{σ}_{R} {w}^{2}}{{Et}^{2}} + \frac{12}{31} {( \frac{h}{t} )}^{2} )$ |

In the above equations, E is Young's modulus of the beam material, l is the length of the critical beam demarcating free and stuck devices, t is the beam thickness, h is the height of the air gap at the post, Γᵣ is the residual stress in the beam, rₒ is the radius of the circular plate, w is the width of the square plate, and v is Poisson's ratio. The majority of these values can be determined either through prediction or through measurement. In particular, the value of the air gap can be determined via observation of the wavelengths of light reflected by the test structure, in order to account for launching of the shoe and beam upward when the sacrificial layer defining the air gap is removed, as discussed in greater detail below. Similarly, the residual stress can be measured either through the fabrication of an alternate test structure, such as a cantilevered beam formed from the layer to be measured. The curvature of this test structure can be measured and used to determine the residual stress within the layer. Adhesion force can then be calculated from the adhesion energy.

In one embodiment, one or more arrays such as array 200 of FIG. 9 may be used to measure compliance with manufacturing requirements as to factors such as stiffness, thin film thickness, and launching. Advantageously, multiple arrays such as array 200 may be provided throughout a wafer, and the arrays may advantageously be oriented in different directions, in order to compare compliance at various locations throughout the wafer. In addition, arrays 200 located on different wafers can be used to identify a lack of uniformity across wafers and/or lots. In on the embodiments, arrays may be provided in which other parameters vary in the array. For example, in certain embodiments arrays may be provided in which the size of the contact area between the movable components and the fixed components varies.

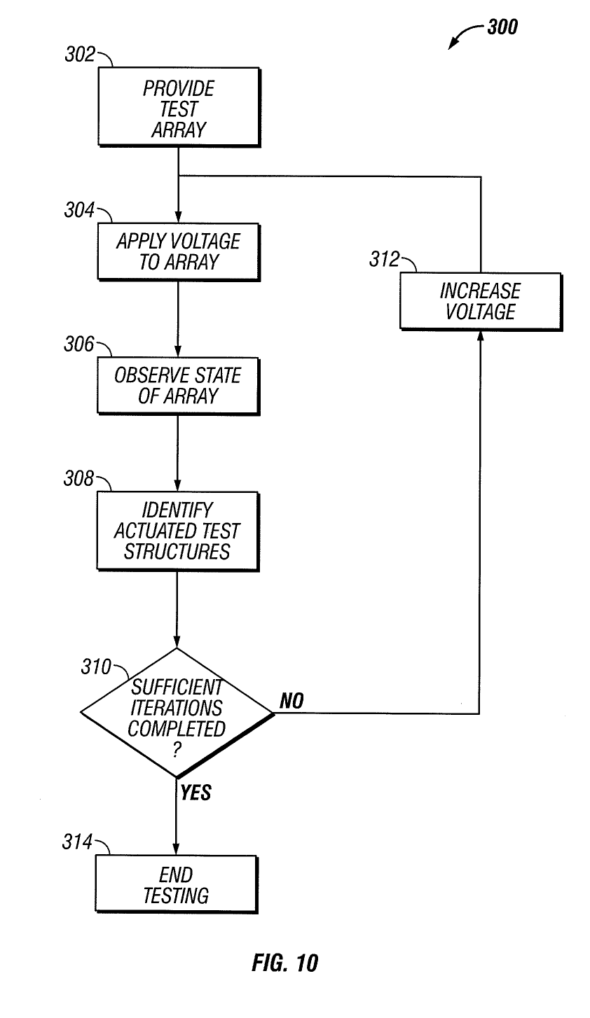

One such testing process is described with respect to FIG. 10. This process 300 begins at a state 302 where one or more arrays of test devices have been fabricated and released, the stiffness of the test devices varying across the array. In step 304, a voltage is applied across the array(s), and for those arrays for which the electrostatic force is greater than the restoring force due to the stiffness of the test structure, the test devices actuate so that they are brought into contact with the optical stack. In step 306, the array is observed, either by a human or in an automated manner (such as by capturing an image of the array. It will be understood that in certain embodiments, particularly in embodiments where there are few arrays, or few test devices, the observation may be done visually by an observer. In other embodiments, the observation may be done via an automated capture of the image, such as by a digital camera or similar device. The automation of this process can significantly speed up the testing process, and can permit delayed analysis of the captured information. The process then moves to a state 308 where the array is analyzed to determine the number of actuated test elements. As discussed with the observation step 306, the process may be done manually by an observer, but may advantageously be done in an automated manner, via analysis of captured images of the array after application of the voltage. In other embodiments, the state of the array may be determined through measurement of the electrical characteristics of the array, a process which may easily be automated.

The process then moves to a state 310 where a determination is made as to whether sufficient iterations of the process have been completed. If fewer iterations than desired have been completed, the process moves to a state 312 where the voltage to be applied is increased. The process then returns to state 302 where the higher voltage is applied, and the array is observed and analyzed. Once sufficient iterations of the process have been completed, the process moves to a state 314 where the testing process ends.

It will be understood that the above process is exemplary, and may be modified in a variety of ways. In certain embodiments, the process may be stopped once it is determined that all test elements being observed have been actuated. In other embodiments, analysis of the data may be delayed until after the data from each iteration has been gathered. In another embodiment, the unactuated array may be observed prior to the application of the actuation voltage, in order to ensure that the air gaps are of the expected height, and to ensure that the air gaps are consistent across the array. This process may include, for example, determination of the wavelength of the light reflected by the unactuated test structures, and subsequent determination of air gap size based on the determined wavelength. Other modifications to the above process are contemplated.

The gathered information may then be used to analyze the actuation voltages necessary to actuate the various test structures. The actual actuation voltages may be compared with predicted results obtained through finite element analysis (FEA) of modeled the test structures having the intended properties, in order to identify deviations from the intended fabrication process. The results of a test structure on one wafer may be compared with the test results on another wafer, in order to ensure conformity across wafers. The results of an array of test elements located at one position on a wafer may be compared with those located at another position on the wafer. In a particular embodiment, test structures oriented in a first direction may be compared to test structures oriented in a second direction, in order to identify residual stress in a particular direction in the deposited layers. In one specific embodiment, the beams of a first array may be oriented orthogonally to the beams of a second array. Similarly, an array of otherwise identical test structures may be oriented in different directions to test such directional effects.

It will also be understood that, as discussed above, data more detailed than a binary analysis of whether a test structure has been actuated or not may be gathered. For instance, the separation of the test structure from the optical stack may be determined with a high degree of accuracy via analysis of the wavelengths of the light reflected by the test structure when the test structures are in an actuated state. Through such analysis, the presence of undesired launching of the movable components can be identified and even quantified, when the movable components move to an unactuated state farther from the optical stack than is desired.

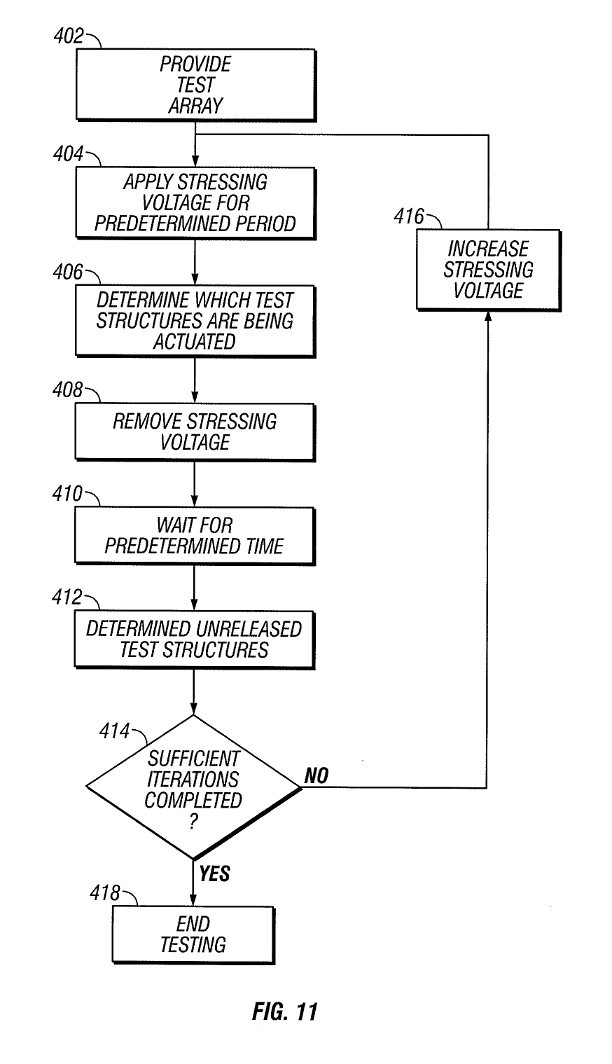

As noted above, a testing process using such an array may also be used to determine the adhesion energy and adhesion force of a particular structure. FIG. 11 illustrates a process 400 wherein information useful in calculation of the actuation energy of a particular test structure may be gathered. The process begins at a stage 402, where an array of released test devices is provided, the test elements having either a varying stiffness or varying contact area across the array, so as to vary either the elastic energy of an actuated test structure or the adhesion energy holding the test structure in place.

Because the adhesion energy of a test device gradually increases over the lifetime of the device, while the restoring forces remains constant, it is desirable to provide a test structure which has properties similar to those of an older MEMS device. As noted above, adhesion forces generally increase over the lifetime of the device while restoring forces remain substantially constant in the absence of factors such as mechanical failure or creep. A suitable test structure for this process may be very compliant, and have a restoring force which is only slightly more than the initial adhesion force. Thus, an array of such compliant test structures may be provided, so that the adhesion forces may quickly overcome the restoring forces of some of the particular test structures. In order to increase the adhesion forces and simulate an older MEMS device, the process moves to a state 404 where a stressing voltage is applied to the test devices for a desired duration. In certain embodiments, the stressing voltage may be applied via a square waveform having an amplitude at the desired voltage and a specific frequency. The square waveform advantageously provides voltage balance when the offset is 0 V.

The duration of the stressing voltage may vary based on the intended analysis. In order to analyze the adhesion forces of test structures near the beginning of their lifetime, the stressing voltage may be applied for only a short time. In such an embodiment, charge buildup may be minimized. In other embodiments, the stressing voltage may be applied for a longer period of time. In addition, although the stressing voltage may comprise a square waveform having an offset of 0V, in other embodiments, residual charge may be present as a result of the manufacturing process, and it may be desirable to alter the offset of the stressing voltage to compensate. The determination of an appropriate offset voltage may include, for example, applying an actuation voltage in the form of a triangle waveform, and determining the difference between the absolute values of the observed positive actuation voltage and the observed negative actuation voltage.

During stressing of the array through the application of voltage, the process moves to a step 406 where images of the test structures are captured and analyzed to determine which test structures are being actuated. Because the voltage is a square waveform, the actuated elements should remain in an actuated position throughout the duration of the actuation voltage application. However, if the actuation voltage is not sufficient to actuate all test structures, the unactuated test structures may be readily identified by observing the reflected light from these test structures. The process then moves to a stage 408 where the stressing voltage is removed. The process may then move to a step 410 where the process waits for a predetermined amount of time, in order to permit temporarily stuck test structures to return to the unactuated state. At step 412, images of the array are again captured and analyzed to determine which of the test structures have failed due to stiction. At step 414, the process determines whether sufficient iterations of the test have occurred. If more iterations are desired (for instance, if it is determined at state 406 that not all test structures are being actuated), the process moves to a state 416 where the stressing voltage is increased, and then returns to the state 404 where the stressing voltage is applied. If sufficient iterations have occurred, the process moves to a state 418 where the process ends. As discussed with respect to the previous testing process, any or all of these steps may advantageously be automated.

After the testing process has been completed to simulate the effect of use under particular conditions, the results of the testing process may be analyzed. In a particular embodiment, as discussed above, the results of the testing process may be used to determine the adhesion forces. When the testing process has concluded, the critical test structures can be identified, at the boundary between actuated and unactuated test devices. Because the peel number, discussed above, represents the balance between the elastic energy which results in a restoring force and the adhesion energy which results in the adhesion force, the adhesion energy can be calculated by setting the peel number equal to 1 and solving for the adhesion energy. The peel number may be determined by calculation of an equation, such as those shown above, or through finite element analysis. By providing a test structure having a shoe of known dimensions in contact with the optical stack, either the stiffness or the contact area can be held constant throughout the array while the other value varies. This is in contrast to test arrays formed from an array of, for example, cantilevered beams having different lengths, in which both the contact area and the stiffness of the beam may vary from beam to beam.

It will be understood that, as discussed above, certain data used to calculate the adhesion energy may be obtained through testing not discussed in the process of FIG. 4. The residual stress within the deposited layers, as well as the distances of the various components from the optical stack, may be determined through the use of additional test structures or measurements, and the particular measurements needed may vary depending on the design of the test structure.

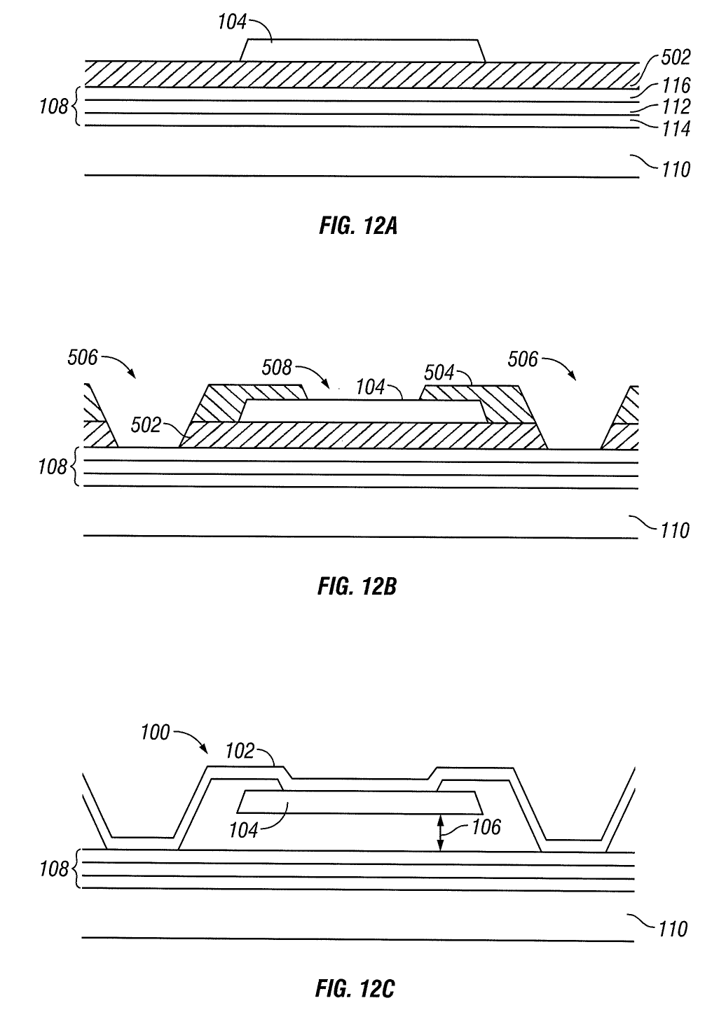

FIGS. 12A-12C illustrate certain steps in the manufacturing of a test device such as the test device 100 of FIG. 8. In FIG. 12A, it can be seen that an optical stack 108 is formed on a light-transmissive substrate 110. The optical stack 108 comprises an electrode layer 114, a partially reflective layer 112, and an overlying dielectric layer 116. Although illustrated for simplicity as continuous layers, it will be understood that the layers may be patterned to form, for example, a desired electrode pattern (not shown). A first sacrificial layer 502 is formed over the optical stack 108, where the thickness of the first sacrificial layer will determine, in the absence of significant launching, the thickness of the interferometric gap 106 of FIG. 8. A layer of reflective material, such as aluminum, is then deposited over the first sacrificial layer 502 and patterned and selectively etched relative to the sacrificial layer 502 to form shoe 104.

In FIG. 12B, it can be seen that a second sacrificial layer 504 is deposited over the patterned shoe, and that the first and second sacrificial layers 504 is patterned and etched to form apertures 506 located on either side of the shoe 104 extending through the sacrificial layers and stopping on the optical stack 108. It can also be seen that an aperture 508 overlying the shoe 104 is formed via the same etch, with the etch stopping on the shoe 104.

Finally, in FIG. 12C it can be seen that a mechanical layer is deposited over the patterned sacrificial layers (see FIG. 12B) and patterned and etched to form beam 102 which extends over and is in contact with a portion of the shoe 104. A release etch is then performed to remove the sacrificial layers and release the test device 100. The test device 100 comprises an interferometric gap between the shoe 104 and the optical stack 108, which may be of a height equal to that of the sacrificial layer 502, unless residual stress in the deposited layers causes the shoe 104 to launch upwards upon release.

It will be understood that the patterning of various layers discussed above will determine the stiffness of the beam 102 or the size of the contact area 118 on the underside of the shoe 104. For example, the distance between the apertures 506 extending through the sacrificial layers will determine the length, and therefore the stiffness, of beam 102. Similarly, the patterning of the shoe 102 will determine its size and therefore the contact area 118. It will also be understood that the fabrication of these test structures is advantageously done in conjunction with the fabrication of MEMS devices elsewhere on the wafer.

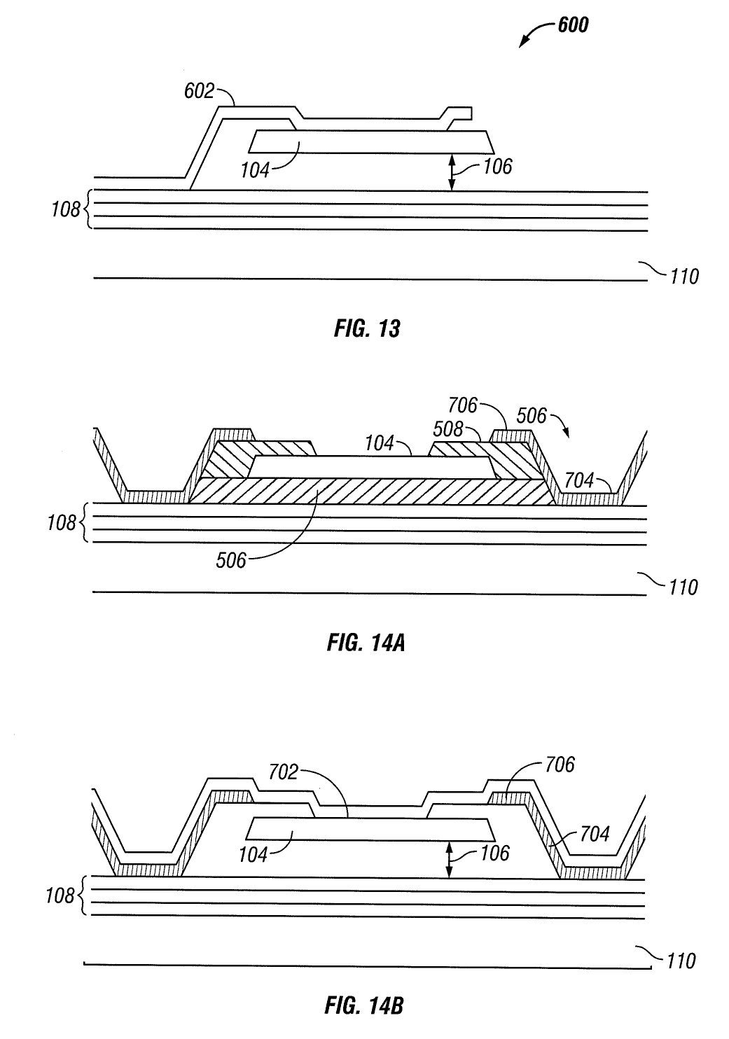

FIG. 13 illustrates an embodiment of process for fabricating an alternative test device 600 in which a shoe is suspended from a cantilevered beam, rather than one fixed at both ends. The process may proceed as discussed with respect to FIGS. 12A-12B, although only one aperture 506 extending through sacrificial layers 502 and 504 need be formed. In FIG. 13, it can be seen that a mechanical layer has been deposited over the patterned sacrificial layers, and patterned and etched to form a beam 602 secured to the optical stack 108 at one end but free at the other end. It will be understood that, as discussed with respect to FIGS. 12A-12C, the stiffness of beam 602 may be controlled by the distance between the aperture 506 and the shoe 104.

FIGS. 14A-14B illustrate a process for fabricating an alternate embodiment of a test structure. This process includes the steps of FIGS. 12A-12B. In FIG. 14A, it can be seen that rather than depositing a mechanical layer directly over the apertures 506, a layer of rigid support material is deposited over the patterned sacrificial layers and then patterned and etched to form support posts 702 located in the apertures 506. These support posts 704 may include wings 706 extending over the sacrificial layer outside of the apertures.

In FIG. 14B it can be seen that a mechanical layer is now deposited, the mechanical layer extending over the support posts 704. The mechanical layer is then patterned as necessary to form beam 702, which in test structure 700 is fixed at both ends to support posts 704. A release etch is performed to remove the sacrificial layers, forming a released test structure 700 having an interferometric gap 106.

Because the support posts 704 may be much stiffer than the overlying beam 102, the stiffness of such a test device 700 may be efficiently adjusted by altering the size of the wings 706 which extend outward from the posts 704, effectively altering the length of the beam 702. Advantageously, the modification of the post wings 706 permits the stiffness of the test devices to be altered without changing the locations of the shoe 104 or the apertures 506 relative to one another. The support posts 704 may be fabricated from a variety of suitable materials, including but not limited to SiO₂.

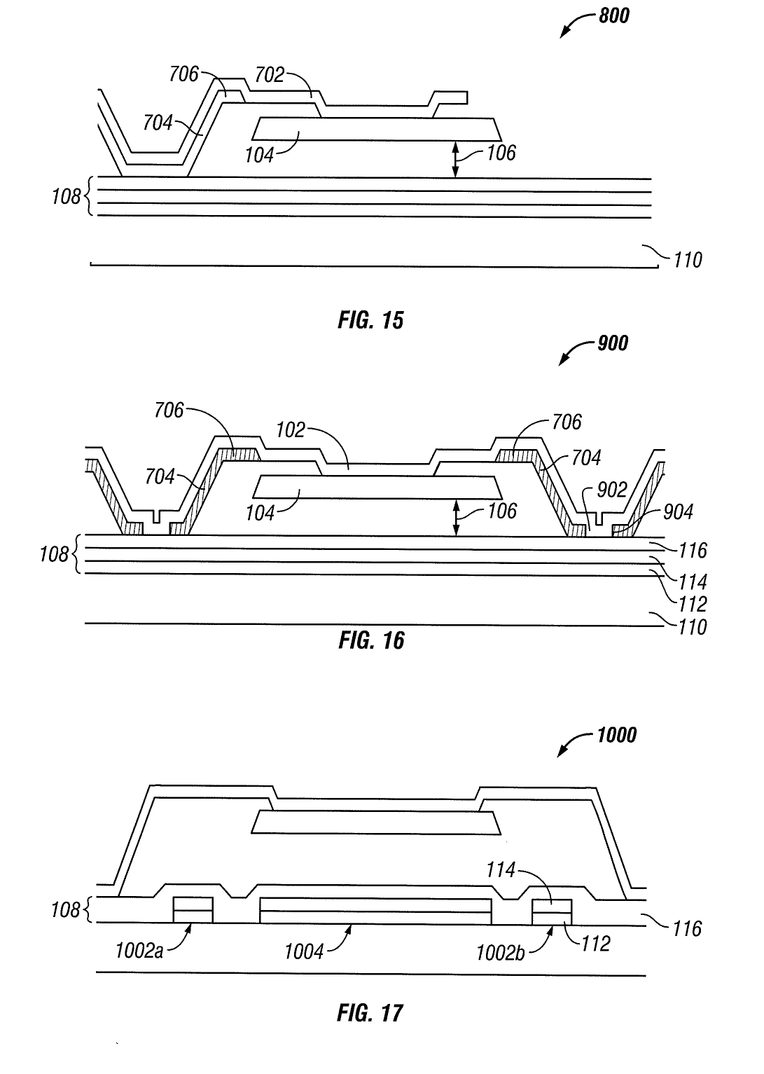

FIG. 15 illustrates the final step in a process for fabricating an embodiment of a test structure having a cantilevered beam with a support post. The process may proceed as described with respect to FIG. 14A, except that only one aperture 506 and support post 704 need be formed per test device. In FIG. 15, it can be seen that a mechanical layer has been deposited over the support post 704 and patterned and etched to form cantilevered beam 702 which is fixed at one end to support post 704 and supports show 104. As discussed with respect to FIGS. 14A-14B, the size of posts wings 706 may be altered to vary the stiffness of the test structure 800.

It will be appreciated that other embodiments of test devices may be fabricated. For example, a simple fixed-fixed or cantilevered beam may be fabricated by depositing a sacrificial layer over an optical stack, patterning the sacrificial layer to form apertures, and forming a beam over the sacrificial layer. The beam may be formed from a reflective material, or may comprise a mechanical sublayer and a reflective sublayer located on the underside of the mechanical sublayer.

While the above description has focused on active test devices which are controlled in part by electrostatic forces resulting from the application of a voltage between two conductive electrodes, other factors can contribute to stiction. In particular, stiction may come about as a result of accumulation of moisture within a package enclosing a MEMS device, and the subsequent collection of moisture on the facing surfaces of the MEMS device causes the surfaces to stick to one another, increasing the adhesion force. One or more passive test devices having a structure similar to one of the test devices discussed above may be used to monitor an increase in adhesion forces due to moisture such as humidity within a test package.

FIG. 16 illustrates such a passive test device, in which a test device 900 comprises a beam 102 and a shoe 104 suspended over an optical stack 108. In the illustrated embodiment, the beam 102 is supported by support posts 704 having wing portions 706 extending outward from the support posts 704, although in other embodiments, the test structure may not comprise support posts, similar to those test structures discussed with respect to, e.g., FIG. 8.

Application of a voltage between beam 102/shoe 104 and optical stack 108 may be inhibited, in order to ensure that the device functions as a passive test device. In certain embodiments, the inhibition of voltage application may be done by shorting the upper layers to the optical stack. In one embodiment, this may be done through a conductive via 902 extending through an aperture 904 at the base of posts 704, as illustrated. The conductive via 902 connects conductive material in the beam 102 to conductive material in the optical stack 108, such as the lower electrode 114 or the partially reflective layer 112. In other embodiments, the shorting may be done elsewhere on the MEMS device. Because the movable portion of the test device 900 is shorted to the conductive electrode, no voltage can be applied between the movable portion and the lower electrode 114. In order to prevent interference with active MEMS elements, the conductive portions of the optical stack 108 shorted to the overlying movable layer may be isolated from portions of the optical stack in an active portion of the MEMS device. Similarly, the beam 102 and shoe 104 may be isolated from surrounding test devices.

If sufficient moisture collects in the MEMS package, the test device 900 will collapse as a result of, e.g., capillary forces. This collapse is often the result of condensation of water vapor within the air gap and meniscus formation within the air gap. The capillary forces that hold the beam and shoe in place as a result of the collapse may be orders of magnitude higher than the restoring force. Because of this, the height of the air gap may control whether a test structure collapses, as compared to the beam stiffness and/or size of the shoe suspended from the beam.

Thus, the test device 900 can be used as a passive humidity monitor in a MEMS package, and can provide information as to the state of the MEMS package without the need for invasive measurements of the MEMS package. Advantageously, an array of test devices 900 having varying properties may be used to provide an indicator of the current amount of moisture in the MEMS package. As noted above, the air gap is often the critical dimension in determining whether a test device collapses. In one embodiment, an array of test devices 900 may be provided, where the height of the air gap in the various test devices 900 varies in the array. As the collapse of such test structures is dependent on the relative humidity and the height of the air gap, the such an array may be used to provide early warning of potentially damaging levels of moisture have collected in the package before the MEMS devices in the package are affected by the moisture. The collapse of particular structures within the array will be indicative of the relative humidity.

In certain embodiments, the air gap may be controlled by providing a sacrificial layer having a varying height, upon which the shoe material can be deposited. However, if a fine gradiation in air gap is desired, it may be prohibitively difficult to provide such a varying sacrificial layer. In other embodiments, particularly in embodiments in which support posts such as the support posts 704 of FIG. 16 are utilized, other parameters may be varied in order to control air gap height. In certain embodiments, upon release of the device through etching of the sacrificial layer, the movable portions of the test structure may move upwards due to residual stresses within those layers. This phenomenon may be referred to as launching, and it will be understood that this launching affects the height of the air gap. As the launching of these movable portions is the result of the stresses within the beams and the stiffness of the beams, by controlling either the stiffness or the stresses within the beams, the launching may be controlled. In a particular embodiment, the size of the wing portions 706 of the support posts 704 may be varied across different test structures. As the support posts 704 may be made significantly stiffer than the beam 102, those test structures in which the wing portions 706 are larger will inhibit launching of the device upon release, due to the additional stiffness provided by the larger wing portions 706.

It will be also understood that while the embodiments of test structures discussed above can be used without modification to measure adhesion between a metal layer and an oxide layer, the test structures may be modified to enable the measurement of adhesion between various combinations of layers. For instance, if a layer of oxide is deposited over the first sacrificial layer prior to deposition of the shoe layer, a shoe having a layer of oxide may be provided, and oxide-to-oxide adhesion forces may be measured. In another embodiment, the portions of the electrode layer underlying the shoe member may be removed, such that the actuation electrode is located close to the edges of the beam and acts on the overlying beam itself. A metallic landing pad, isolated from the lower electrode, may then be provided underneath the shoe to test metal-to-metal adhesion forces.

Similarly, as one potential source of adhesion forces in the above test devices is the existence of trapped charge in the dielectric layer, the test structures may be modified in a manner similar to that discussed above, where the portion of the electrode layer underlying the shoe is removed, such that the dielectric layer underlying the shoe remains substantially free of trapped charge. With such a modified test structure, one can measure adhesion forces resulting from factors other than trapped charge, such as, for example, Van der Waals interactions, capillary forces, chemical bonds (e.g., hydrogen or other bonds), solid bridging (where hard material, e.g., aluminum oxide, on one surface penetrates soft materal, e.g., aluminum, on another surface brought into contact with the other surface), and particulates or other contamination (which may be particularly prevalent in MEMS devices which are formed using a wet release etch). Similarly, if adhesion is measured using a device modified in such a manner and an equivalent unmodified device, the amount of adhesion due to trapped charge can be estimated by comparing the two values of adhesion forces obtained.

FIG. 17 illustrates a modified test structure which may be useful for isolating non-electrostatic adhesion forces. The test structure 1000 differs from the test structure of FIG. 8 in that the conductive portions of the optical stack have been divided into multiple conductive portions. These conductive portions comprise at least the lower electrode, and in many embodiments the partially reflective layer, as well. In the illustrated embodiment, the conductive portions have been patterned to form two driving electrodes, 1002a and 1002b, as well as a conductive portion 1004 positioned underneath the shoe and isolated from the driving electrodes. The driving electrodes 1002a,b will act on the portions of the beam 102 not obstructed by the shoe. In certain embodiments the isolated conductive portion 1004 may advantageously be shorted to the overlying movable portions of the test structure, including the beam 102 and the shoe 104. Because the isolated conductive portion is not exposed to the driving voltage applied to the driving electrodes, charge buildup within the portion of the optical stack overlying the shoe can be avoided, and will not contribute to the adhesion forces holding the shoe in place after actuation of the test structure. Thus, the test structure 1000 can be used to measure non-electrostatic adhesion forces.

It will be understood that various combinations of the above embodiments are possible. Various other combinations of the methods discussed above are contemplated and are within the scope of the invention. In addition, it will be understood that structures formed by any of the methods above may be utilized in combination with other methods of forming structures within MEMS devices. Similarly, the methods of testing described herein may be used in combination with other methods of testing MEMS devices

It will also be recognized that the order of layers and the materials forming those layers in the above embodiments are merely exemplary. Moreover, in some embodiments, other layers, not shown, may be deposited and processed to form portions of an MEMS device or to form other structures on the substrate. In other embodiments, these layers may be deposited in a different order, or composed of different materials, as would be known to one of skill in the art.

It is also to be recognized that, depending on the embodiment, the acts or events of any methods described herein can be performed in other sequences, may be added, merged, or left out altogether (e.g., not all acts or events are necessary for the practice of the methods), unless the text specifically and clearly states otherwise.

While the above detailed description has shown, described, and pointed out novel features of the invention as applied to various embodiments, it will be understood that various omissions, substitutions, and changes in the form and details of the device of process illustrated may be made by those skilled in the art without departing from the spirit of the invention. As will be recognized, the present invention may be embodied within a form that does not provide all of the features and benefits set forth herein, as some features may be used or practiced separately from others.

What is claimed is:

1. An array of MEMS devices, comprising:
an optical stack located over a substrate, the optical stack comprising apartially reflective layer;
an array of flexible beams spaced apart from the optical stack by an air gap, wherein application of a voltage across said beams and said optical stack is inhibited; and
reflective surfaces positioned on the side of the beams facing the optical stack, wherein sustained adhesion of particular beams to the optical stack is indicative of non-electrostatic adhesion forces within the MEMS device.

2. The array of claim 1, wherein the height of the air gap varies in the array.

3. The array of claim 2, additionally comprising a plurality of support posts supporting the flexible beams, wherein the support posts comprise outwardly extending wing portions, and wherein the size of the outwardly extending wing portions varies in the array.

4. The array of claim 1, additionally comprising a conductive via extending between conductive portions of the flexible beam and conductive portions of the optical stack.

5. A method of fabricating an array of test devices, comprising:
forming an optical stack over a substrate, the optical stack comprising a partially reflective layer; and
forming a plurality of beams spaced apart from the substrate by an air gap, wherein the beams are not electrostatically actuatable towards the optical stack, and wherein the beams comprise a reflective surface facing the optical stack.

6. The method of claim 5, the method additionally comprising forming a plurality of conductive vias, each via extending between a conductive portion of the optical stack and a conductive portion of one of the plurality of beams.

7. The method of claim 5, wherein the height of the air gap varies in the array.

8. The method of claim 7, additionally comprising forming a plurality of support structures, wherein the plurality of support structures comprise outwardly extending wing portions, and wherein the size of the wing portions varies in the array.

9. A method of testing an array of MEMS devices, comprising:
providing an array of beams spaced apart from an optical stack by an air gap, wherein the beams comprise a reflective layer on their lower surface and have a stiffness that varies across the array, and wherein the optical stack comprises a partially reflective layer and a lower electrode;
determining a predicted actuation voltage for each of the array of beams;
applying a first voltage between the array of beams and the lower electrode;
determining, without the aid of an external interferometer, which of the array of beams have been actuated through the air gap towards the electrode due to application of the first voltage; and
comparing the first voltage with the predicted actuation voltages for each of the beams.

10. The method of claim 9, additionally comprising:
applying a second voltage between the array of beams and the electrode; and
determining, without the aid of an external interferometer, which of the array of beams have been actuated through the air gap towards the electrode due to application of the second voltage; and
comparing the second voltage with the predicted actuation voltages for each of the beams.

11. The method of claim 9, additionally comprising:
providing a second array of beams spaced apart from an optical stack by an air gap, wherein the beams comprise a reflective layer on their lower surface and have a stiffness that varies across the second array;
determining a predicted actuation voltage for each of the second array of beams;
applying said first voltage across the second array of beams and the second electrode;
determining, without the aid of an external interferometer, which of the second array of beams have been actuate through the air gap towards the electrode due to application of the first voltage; and
comparing the second voltage with the predicted actuation voltage for each of the array of beams.

12. The method of claim 9, wherein the second array of beams are oriented in a different direction than the first array of beams.

13. The method of claim 9, additionally comprising determining the height of the air gap prior to applying said first voltage.

14. The method of claim 9, wherein determining which of the array of beams have been actuated comprises determining the wavelength of the light reflected by the MEMS devices.

15. The method of claim 9, wherein determining which of the array of beams have been actuated comprises determining the capacitance of the MEMS devices.

16. A method of testing an array of MEMS devices, comprising:
providing an array of beams having a reflective layer on their lower surface, wherein said beams are spaced apart from a partially reflective layer and a first electrode by an air gap, wherein the stiffness of the beams varies across a length of the array;
applying a first voltage between the array of beams and the first electrode sufficient to cause each of the plurality of beams to actuate through the air gap and come into contact with an underlying layer;
releasing the first voltage;
determining, without the aid of an external interferometer, which of the array of beams remain unreleased; and
determining the adhesion energy holding the unreleased beams in place.

17. The method of claim 16, additionally comprising
calculating a restoring force of the stiffest unreleased beam; and
utilizing the calculated restoring force to determine the adhesion energy.

18. The method of claim 16, wherein applying a first voltage comprises applying a cyclical voltage for a predetermined period of time.

19. The method of claim 16, additionally comprising determining the height of the air gap prior to applying said first voltage.

20. The method of claim 16, wherein determining which of the array of beams have been actuated comprises determining the wavelength of the light reflected by the MEMS devices.

21. The method of claim 16, wherein determining which of the array of beams have been actuated comprises determining the capacitance of the MEMS devices.

22. A method of testing an array of MEMS devices, comprising:
providing an array of beams having a reflective contact area on their lower surface, wherein said beams are spaced apart from a partially reflective layer and a first electrode by an air gap, wherein the size of the contact area varies across a length of the array;
applying a first voltage between the array of beams and the first electrode sufficient to cause each of the plurality of beams to actuate through the air gap and come into contact with an underlying layer;
releasing the first voltage;
determining, without the aid of an external interferometer, which of the array of beams remain unreleased; and
determining the adhesion energy holding the unreleased beams in place.

23. The method of claim 22, additionally comprising
determining a restoring force of the unreleased beam having the largest contact area; and
determining adhesion energy using the restoring force.

24. The method of claim 22, additionally comprising determining the height of the air gap prior to applying said first voltage.

25. The method of claim 22, wherein determining which of the array of beams have been actuated comprises determining the wavelength of the light reflected by the MEMS devices.

26. The method of claim 22, wherein determining which of the array of beams have been actuated comprises determining the capacitance of the MEMS devices.

27. A method of testing an array of MEMS devices, comprising:
providing an array of beams spaced apart from a lower electrode by an air gap, wherein the beams comprise a conductive portion and have a stiffness that varies across the array;
determining a predicted actuation energy for each of the array of beams;
applying a first voltage between the array of beams and the lower electrode;
determining, based on the electrical characteristics of the MEMS devices, which of the array of beams have been actuated through the air gap towards the electrode due to application of the first voltage; and
comparing the first voltage with the predicted actuation voltages for each of the beams.

28. The method of claim 27, wherein determining which of the array of beams have been actuated comprises determining the capacitance of the MEMS devices.

29. A method of testing an array of MEMS devices, comprising:
providing an array of beams spaced apart from a partially reflective layer and a first electrode by an air gap, wherein the stiffness of the beams varies across a length of the array;
applying a first voltage between the array of beams and the first electrode sufficient to cause each of the plurality of beams to actuate through the air gap and come into contact with an underlying layer;
releasing the first voltage;
determining, based on the electrical characteristics of the MEMS devices, which of the array of beams remain unreleased; and
determining the adhesion energy holding the unreleased beams in place.

30. The method of claim 29 wherein determining which of the array of beams remain unreleased comprises determining the capacitance of the MEMS devices.

31. A method of testing an array of MEMS devices, comprising:
providing an array of beams having a contact area on their lower surface, wherein said beams are spaced apart from a first electrode by an air gap, and wherein the size of the contact area varies across a length of the array;
applying a first voltage between the array of beams and the first electrode sufficient to cause each of the plurality of beams to actuate through the air gap and come into contact with an underlying layer;
releasing the first voltage;
determining, based on the electrical characteristics of the MEMS devices, which of the array of beams remain unreleased; and
determining the adhesion energy holding the unreleased beams in place.

32. The method of claim 31, wherein determining which of the array of beams remain unreleased comprises determining the capacitance of the MEMS devices.

33. An array of MEMS devices, comprising:
means for reflecting incident light;
means for partially reflecting incident light;
means for inhibiting the application of a voltage between said reflecting means and said partially reflecting means; and
means for restoring said reflecting means to positions away from said partially reflecting means, wherein the restoration of particular reflecting means is indicative of non-electrostatic adhesion forces within the MEMS device.

34. A computer readable medium, comprising instructions for testing an array of MEMS devices, the instructions comprising:
instructions for applying a voltage across an array of test structures, wherein the test structures comprise integrated interferometric modulators; and
instructions for determining which of the test structures have actuated.

35. A computer readable medium, comprising instructions for testing an array of MEMS devices, the instructions comprising:
instructions for applying a time-varying voltage across an array of test structures for a predetermined time period, wherein the test structures comprise integrated interferometric modulators; and
instructions for determining which of the test structures have returned to an unactuated state.
